(19) United States
(12) Patent Application Publication
(10) Pub. No.: US 2019/0043897 A1
(43) Pub. Date: Feb. 7, 2019

(54) METHOD FOR FABRICATING ARRAY SUBSTRATE, ARRAY SUBSTRATE AND DISPLAY DEVICE

(71) Applicants: BOE TECHNOLOGY GROUP CO., LTD., Beijing (CN); CHONGQING BOE OPTOELECTRONICS TECHNOLOGY CO., LTD., Chongqing (CN)

(72) Inventors: Maokun TIAN, Beijing (CN); Wei SHEN, Beijing (CN); Zhonghao HUANG, Beijing (CN); Zhaojun WANG, Beijing (CN); Dalong MAO, Beijing (CN)

(21) Appl. No.: 16/023,840

(22) Filed: Jun. 29, 2018

(30) Foreign Application Priority Data
Aug. 3, 2017 (CN) 201710657125.5

(51) Int. Cl. H01L 27/12

(52) U.S. Cl. CPC H01L 27/1262; G02F 1/1368; H01L 27/1248

(57) ABSTRACT

The present disclosure describes a method for fabricating an array substrate, an array substrate, and a display device. The method includes the following steps: forming a gate electrode on a substrate; forming a gate insulating layer on a side of the gate electrode distal to the substrate; and forming an active layer and a source-drain metal sequentially on a side of the gate insulating layer distal to the gate electrode; forming a protection layer for the source-drain metal on a side of the source-drain metal distal to the gate insulating layer; and etching portion of the source-drain metal corresponding to the channel region to form a source electrode and a drain electrode.

### CROSS-REFERENCE TO RELATED APPLICATIONS

The present application claims the priority of Chinese Patent Application No. 201710657125.5, filed on Aug. 3, 2017, the contents of which are incorporated herein in their entirety by reference.

### TECHNICAL FIELD

The present disclosure relates to the field of displaying technologies, and in particular, to a method for fabricating an array substrate, an array substrate, and a display device using the array substrate.

### BACKGROUND

Thin film transistor liquid crystal displays (TFT-LCDs), with characteristics such as small size, low power consumption and no radiation, have been developed rapidly in recent years, and have dominated the current flat panel display market. However, current methods for fabricating array substrates, the array substrates, and display devices using the array substrates still need to be improved.

For example, thin film transistor liquid crystal displays generally have a defect of low aperture ratio, which may be caused by large etched steps on two ends of the source electrode and the drain electrode. In some cases, the source electrode and drain electrode are formed by two wet etching processes. Due to the existence of a certain error in the wet etching processes, large etched steps may be formed on the two ends of the source electrode and the drain electrode after the two wet etching processes, thereby increasing the area of the non-displaying area and reducing the aperture ratio. In addition, in the process of forming an active layer, an active layer film needs to be dry etched, while the source electrode and the drain electrode on the upper surface of the active layer need to be wet etched. Such difference in etching processes may also cause large etched steps being formed on two ends of the source electrode and the drain electrode, thereby affecting the aperture ratio. Even if the source electrode and the drain electrode are formed by dry etching, large etched steps may still be formed on two ends of the source electrode and the drain electrode due to the error in the etching processes, thereby affecting the aperture ratio.

### SUMMARY

In view of this, according to one aspect of the present disclosure, a method for fabricating an array substrate is proposed. The method includes the steps of forming a gate electrode on a substrate; forming a gate insulating layer on a side of the gate electrode distal to the substrate; forming an active layer and a source-drain metal sequentially on a side of the gate insulating layer distal to the gate electrode; forming a protection layer for the source-drain metal on a side of the source-drain metal distal to the gate insulating layer; and etching a portion of the source-drain metal corresponding to a channel region to form a source electrode and a drain electrode.

According to an embodiment of the present disclosure, the step of forming a gate electrode on the substrate includes the steps of: depositing a first metal layer on the substrate; and forming the gate electrode by a first patterning process based on the first metal layer.

According to an embodiment of the present disclosure, the method further includes performing the following step simultaneously with the step of forming the gate electrode on the substrate: forming a gate electrode line and a common electrode line by the first patterning process based on the first metal layer.

According to an embodiment of the present disclosure, the step of forming the active layer and the source-drain metal sequentially on the side of the gate insulating layer distal to the gate electrode includes the steps of: depositing an active layer film and a second metal layer sequentially on the side of the gate insulating layer distal to the gate electrode; and forming the active layer and the source-drain metal by a second patterning process based on the active layer film and the second metal layer.

According to an embodiment of the present disclosure, the method further includes performing the following step simultaneously with the step of forming the active layer and the source-drain metal sequentially on the side of the gate insulating layer distal to the gate electrode: forming a data line by the second patterning process based on the second metal layer.

According to an embodiment of the present disclosure, the step of forming the protection layer for the source-drain metal on the side of the source-drain metal distal to the gate insulating layer includes the following steps: forming a first portion of a first transparent conductive layer on the side of the source-drain metal distal to the gate insulating layer; and forming the protection layer for the source-drain metal by a third patterning process based on the first portion of the first transparent conductive layer, wherein the protection layer for the source-drain metal covers at least the sidewalls of the source-drain metal and exposes a surface of a portion of the source-drain metal corresponding to the channel region.

According to an embodiment of the present disclosure, the method further includes performing the following steps simultaneously with the step of forming the protection layer for the source-drain metal on the side of the source-drain metal distal to the gate insulating layer: forming a second portion of the first transparent conductive layer on a portion of the gate insulating layer distal to the gate electrode and without the active layer and the source-drain metal formed thereon; and forming a pixel electrode by the third patterning process based on the second portion of the first transparent conductive layer.

According to an embodiment of the present disclosure, the step of etching the portion of the source-drain metal corresponding to the channel region to form the source electrode and the drain electrode includes the step of: etching the portion of the source-drain metal corresponding to the channel region by using the protection layer for the source-drain metal as a mask to form the source electrode and the drain electrode.

According to an embodiment of the present disclosure, the method further includes the step of performing the following step simultaneously with the step of etching the portion of the source-drain metal corresponding to the channel region to form the source electrode and the drain electrode: performing a thinning process to the channel region of the active layer.

According to an embodiment of the present disclosure, the method further includes the step of: forming a passivation layer by a fourth patterning process, wherein the passivation layer covers at least the protection layer for the source-drain metal and the channel region of the active layer.

According to an embodiment of the present disclosure, the method further includes performing the following step simultaneously with the step of forming the passivation layer: forming a connecting hole by the fourth patterning process.

According to an embodiment of the present disclosure, the method further includes the step of: depositing a second transparent conductive layer and forming a common electrode by a fifth patterning process.

According to another aspect of the present disclosure, an array substrate is proposed. The array substrate includes: a substrate; a gate electrode formed on the substrate; a gate insulating layer formed on a side of the gate electrode distal to the substrate; an active layer formed on a side of the gate insulating layer distal to the gate electrode; a source electrode and a drain electrode formed on a side of the active layer distal to the gate insulating layer; and a pixel electrode and a protection layer for the source-drain metal, wherein the pixel electrode and the protection layer for the source-drain metal are formed by a first transparent conductive layer, and the protection layer for the source-drain metal covers at least sidewalls of the source electrode and the drain electrode and exposes a surface of a channel region of the active layer.

According to an embodiment of the present disclosure, the array substrate further includes: a gate electrode line and a common electrode line, wherein the gate electrode line, the common electrode line and the gate electrode are formed by a first metal, and the gate electrode line and the common electrode line are formed in a same layer as the gate electrode and are formed simultaneously with the gate electrode; a data line, wherein the data line and the source electrode and the drain electrode are formed by a second metal, and the data line is formed in a same layer as the source electrode and the drain electrode and is formed simultaneously with the source electrode and the drain electrode; a passivation layer, wherein the passivation layer covers at least the protection layer for the source-drain metal and the channel region of the active layer, and the passivation layer includes a connecting hole; and a common electrode, wherein the common electrode is formed by a second transparent conductive layer.

According to another aspect of the present disclosure, there is also proposed a display device including the aforementioned array substrate.

### BRIEF DESCRIPTION OF THE DRAWINGS

The above and/or additional aspects and advantages of the present disclosure will become apparent from the following description of the embodiments in conjunction with the accompanying drawings, wherein the embodiments are illustrated in the accompanying drawings. The same or similar reference numerals denote the same or similar elements or elements having the same or similar functions throughout the accompanying drawings, wherein:

FIG. 1 is a schematic flow chart illustrating a method for fabricating an array substrate according to an embodiment of the present disclosure;

FIG. 2 is a schematic view illustrating a structure of part of an array substrate according to an embodiment of the present disclosure;

FIG. 3 is a schematic view illustrating a structure of an exemplary array substrate;

FIG. 4 is a schematic view illustrating a structure of part of an array substrate according to an embodiment of the present disclosure;

FIG. 5 is a schematic view illustrating a structure of an array substrate according to an embodiment of the present disclosure;

FIG. 6 is a schematic view illustrating a structure of an array substrate according to another embodiment of the present disclosure; and

FIG. 7 is a schematic view illustrating a structure of an array substrate according to still another embodiment of the present disclosure.

### DETAILED DESCRIPTION

The embodiments of the present disclosure will be described in detail below. The embodiments described below with reference to the accompanying drawings are exemplary, which are merely used to explain the present disclosure and should not be construed as limitations to the present disclosure.

In the description of the present disclosure, the orientations or positional relationships indicated by the terms such as “upper”, “lower” are the orientations or positional relationships illustrated in the drawings, which is merely illustrated for facilitating the description of the present disclosure, and does not require the present disclosure to be constructed and operated in the particular orientation. Thus, they should not to be construed as limitations to the present disclosure.

According to one aspect of the present disclosure, a method for fabricating an array substrate is proposed. Referring to FIG. 1, the method includes the following steps S100-S500.

At step S100, a gate electrode is formed on a substrate.

Specifically, a first metal layer is deposited on a substrate firstly, and then the gate electrode is formed by a first patterning process based on the first metal layer.

According to an embodiment of the present disclosure, the detailed manner of implementing the first patterning process is not particularly limited as long as a gate electrode can be formed. For example, the first patterning process may be etching the first metal layer by using a photolithography technique to form a gate electrode. Specifically, the first patterning process may include: coating a layer of photoresist on the first metal layer firstly, and then exposing and developing the photoresist using a predefined mask, afterwards, etching the first metal layer and finally stripping the photoresist to form the gate electrode.

According to an embodiment of the present disclosure, in order to further simplify fabricating steps of the method, a gate electrode line and a common electrode line may also be formed, simultaneously with forming of the gate electrode, on the substrate based on the first metal layer by the first patterning process. To this end, the shape of a predefined mask needs to be designed. That is, the mask used in the first patterning process includes a pattern for the gate electrode, the gate electrode line, and the common electrode line; and the gate electrode, the gate electrode line, and the common electrode line can be formed at the same time after the photoresist is exposed and developed and the first metal layer is etched by using the mask.

At step S200, a gate insulating layer is formed on a side of the gate electrode distal to the substrate.

Through this step, the gate electrode and the active layer obtained in the subsequent steps can be effectively isolated from other layers or components.

According to the embodiments of the present disclosure, the specific material and fabricating manner of the gate insulating layer are not particularly limited, and can be selected by those skilled in the art according to actual needs. For example, the gate insulating layer may be formed using an oxide such as a metal oxide or a silicon oxide.

At step S300, an active layer and a source-drain metal are sequentially formed on a side of the gate insulating layer distal to the gate electrode.

Specifically, an active layer film and a second metal layer are sequentially deposited on a side of the gate insulating layer distal to the gate electrode firstly, and then the active layer and the source-drain metal are formed by a second patterning process based on the active layer film and the second metal layer.

It should be noted that, the second patterning process is similar to the first patterning process, and the specific manner of implementing the second patterning process is not particularly limited. According to a specific embodiment of the present disclosure, the second patterning process may also include procedures of coating, exposing and developing of the photoresist, etching with the photoresist, and stripping of the photoresist.

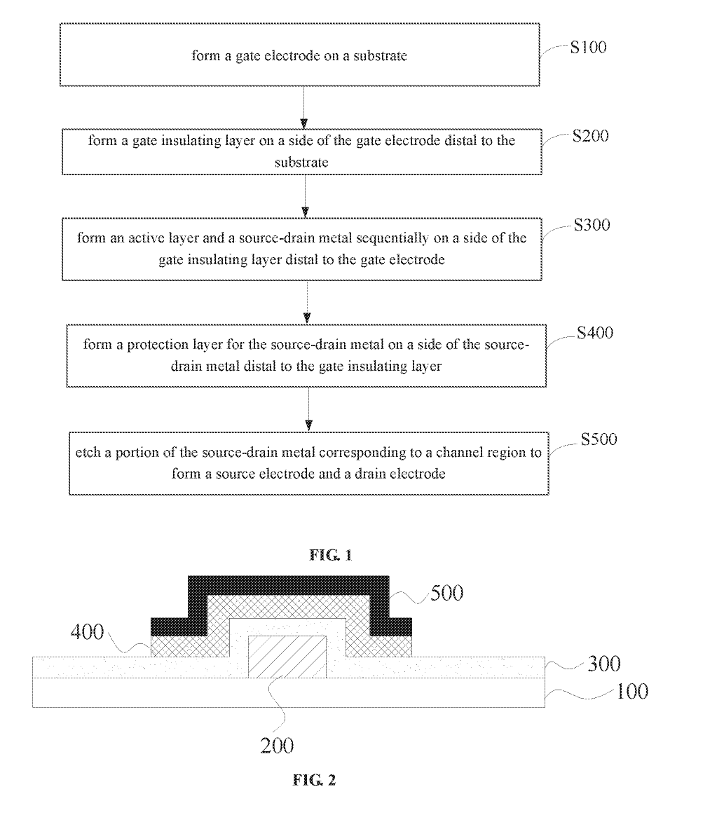

According to an embodiment of the present disclosure, the mask used in the second patterning process has a pattern for the source-drain metal. It should be noted that, as illustrated in FIG. 2, the active layer has a substantially same shape as the source-drain metal. Therefore, the active layer may be fabricated by using a mask having the pattern for the source-drain metal. In some cases, in the fabricating process of the active layer and the source electrode and drain electrode, the active layer is fabricated by using a mask for the active layer, and then the source electrode and drain electrode are fabricated by using a mask for the source electrode and drain electrode. In contrast, the embodiment of the present disclosure can reduce the number of used masks by one, thereby simplifying the production process and saving costs.

According to an embodiment of the present disclosure, in order to simplify the fabricating steps of the method, a data line may also be formed, simultaneously with forming of the active layer and the source-drain metal, by the second patterning process based on the second metal layer. To this end, the shape of a predefined mask needs to be designed. That is, the mask used in the second patterning process has a pattern for the source-drain metal and the data line, such that the active layer, the source-drain metal, and the data line can be simultaneously formed.

According to an embodiment of the present disclosure, in this step, a half-tone mask is not used during the fabrication of the active layer, the source-drain metal, and the data line, thereby reducing the step of ashing by using the half-tone mask. Thereby, oxidation of the metal during the ashing process can be avoided, such that the conductive properties of the source-drain metal are not affected, thereby ensuring the conductivity of the source electrode and drain electrode subsequently formed by the source-drain metal, improving the performance of the final product.

At step S400, a protection layer for the source-drain metal is formed on a side of the source-drain metal distal to the gate insulating layer.

Specifically, a first portion of a first transparent conductive layer is deposited on a side of the source-drain metal distal to the gate insulating layer firstly, and then the protection layer for the source-drain metal is formed by a third patterning process based on the first portion of the first transparent conductive layer, wherein the protection layer for the source-drain metal covers at least the sidewalls of the source-drain metal and exposes a surface of a portion of the source-drain metal corresponding to the channel region.

According to an embodiment of the present disclosure, the third patterning process may also be similar to the first patterning process, and the specific manner of implementing the third patterning process is not particularly limited. That is, the third patterning process may also include a process of coating, exposing and developing of the photoresist, etching with the photoresist, and stripping of the photoresist. In order to simplify the fabricating steps of the method, a second portion of the first transparent conductive layer may also be formed, simultaneously with fabricating the source-drain metal by the third patterning process, on a portion of the gate insulating layer, which is on a side of the gate insulating layer distal to the gate electrode and without the active layer and the source-drain metal formed thereon; and then a pixel electrode may also be formed by the third patterning process based on the second portion of the first transparent conductive layer. Therefore, according to the embodiment of the present disclosure, the mask used in the third patterning process has a pattern for the pixel electrode and the protection layer for the source-drain metal, such that the pixel electrode and the protection layer for the source-drain metal can be simultaneously obtained.

In addition, in this step, when depositing the first transparent conductive layer, the source-drain metal 500 can effectively protect the channel region of the active layer 400 and prevent crystallites of the first transparent conductive layer (e.g., indium tin oxide (ITO)) from remaining in the channel region, thereby improving the performance of the TFT.

At step S500, a portion of the source-drain metal corresponding to the channel regions is etched to form the source electrode and drain electrode.

The structure of the array substrate obtained according to this step is illustrated in FIG. 5.

In some cases, etched steps may be formed at two ends of the source electrode and the drain electrode during etching of the portion of the source-drain metal corresponding to the channel region. Specifically, referring to FIG. 3, when a portion of the source-drain metal corresponding to the channel region is etched to form the source electrode and the drain electrode, the metal at two ends of the source-drain metal may be etched once more to form etched steps (as illustrated in the circled area in FIG. 3), which can result in a reduction in the aperture ratio of the final product.

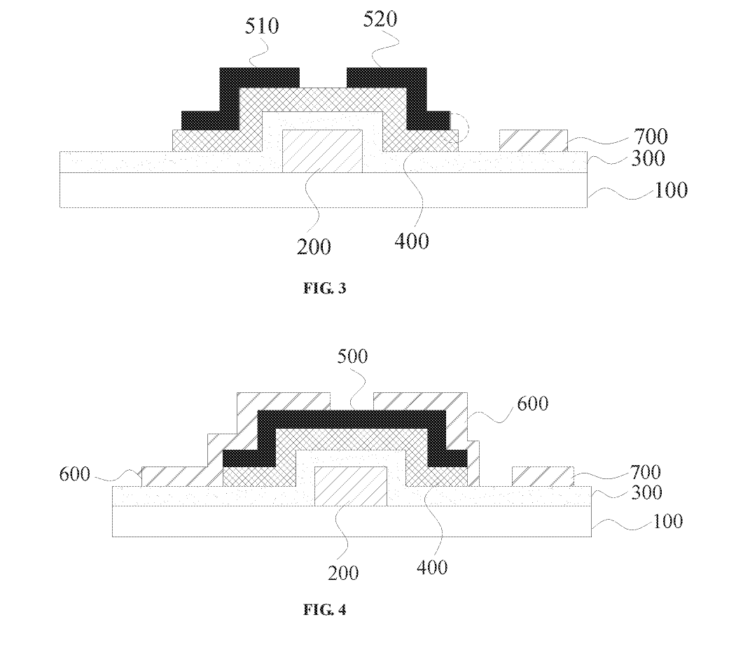

However, according to the above-described step S400, the protection layer for the source-drain metal is formed on the side of the source-drain metal distal to the gate insulating layer. Referring to FIG. 4, the protection layer for the source-drain metal covers at least the sidewalls of the source-drain metal and exposes a surface of a portion of the source-drain metal corresponding to the channel region. Therefore, the metal at two ends of the source-drain metal can be protected from being etched when the portion of the source-drain metal corresponding to the channel region is etched, such that etched steps can be avoided at two ends of the source electrode and the drain electrode, and thinning of the source electrode and drain electrode, increase of aperture ratio of the final product, and increase of pixel density can be achieved. In addition, although the protection layer for the source-drain metal 600 occupies a certain space, it does not affect the aperture ratio since it is formed by the transparent conductive material.

According to an embodiment of the present disclosure, after the source electrode and the drain electrode are formed, the channel region of the active layer may be thinned by using the protection layer for the source-drain metal as a mask, in order to form a TFT channel and improve the performance of the TFT. According to an embodiment of the present disclosure, the specific manner of thinning the channel region in this step is not particularly limited. For example, the active layer of the channel region may be thinned by dry etching or wet etching according to an embodiment of the present disclosure. When dry etching is used, specifically, etching gas such as SF₆, HCl, Cl₂, and He can be used. The etching gas would not react with the protection layer for the source-drain metal and the source-drain metal, so that no additional mask is required.

According to an embodiment of the present disclosure, the method may further include a step of forming a passivation layer by a fourth patterning process, wherein the passivation layer covers at least the protection layer for the source-drain metal and the channel region of the active layer. According to an embodiment of the present disclosure, in order to simplify fabricating steps of the method, a connecting hole may be formed, simultaneously with forming of the passivation layer, by the fourth patterning process. According to an embodiment of the present disclosure, the specific manner of the fourth patterning process is not particularly limited, as long as the passivation layer can be formed. For example, the fourth patterning process may also include a photolithography process, and the mask used during the photolithography process has a pattern for the passivation layer and the connecting hole. Thereby, the passivation layer and the connecting hole can be obtained synchronously.

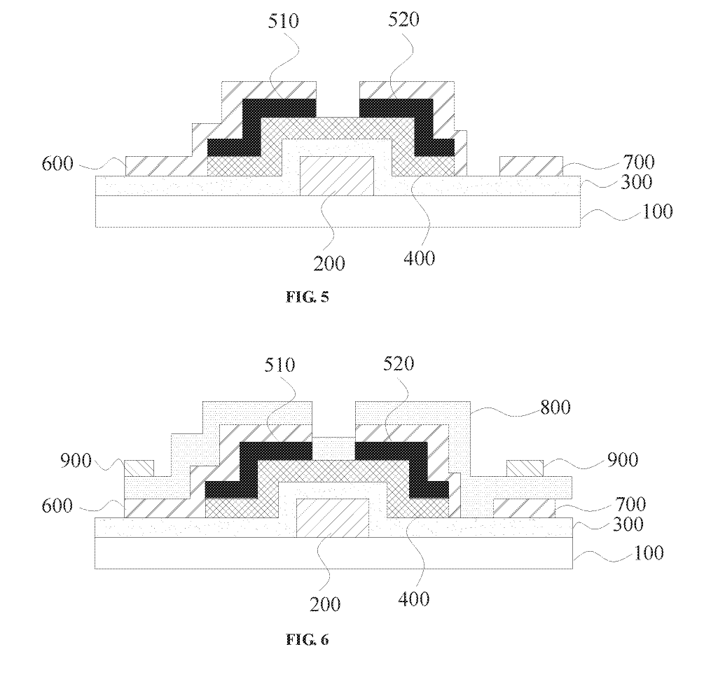

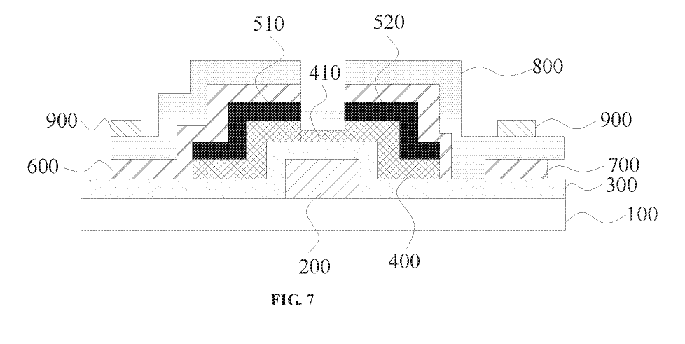

According to an embodiment of the present disclosure, a step of depositing a second transparent conductive layer and forming a common electrode by a fifth patterning process is further included. The specific embodiment of the fifth patterning process is also not particularly limited. For example, the fifth patterning process may include a photolithography process, and the mask used in the photolithography process has a pattern for the common electrode. According to an embodiment of the present disclosure, the second transparent conductive layer forming the common electrode may be ITO. According to an embodiment of the present disclosure, the common electrode may be connected with the above-described connecting hole (not shown). Thereby, the electrical connection with the common electrode can be achieved. The array substrate finally obtained is illustrated in FIG. 6 or FIG. 7. It should be noted that, the drawings are merely schematic and should not be construed as limitations to the present disclosure.

It should be noted that “first patterning process”, “second patterning process”, “third patterning process”, “fourth patterning process” and “fifth patterning process” are merely different names for the patterning processes used, and specific parameters of the processes do not have to be the same and can be selected by a person skilled in the art according to specific conditions. For example, the patterning process may be a photolithography process or an ink jet printing process; the photoresist used in the photolithography processes may be the same or different; the etching process may be a wet etching or a dry etching, as long as the corresponding pattern can be formed.

It should be noted that, the method described in the above embodiments can also improve the source-drain metal corrosion or oxidation caused by dry strip process, thereby improving the TFT characteristics and improving the product yield.

According to another aspect of the present disclosure, an array substrate is proposed. The array substrate may be the array substrate fabricated by the foregoing method. As such, the array substrate may have the same features and advantages of the array substrate fabricated using the previously described method. According to an embodiment of the present disclosure, as illustrated in FIG. 5, the array substrate includes a substrate 100, a gate electrode 200, a gate insulating layer 300, an active layer 400, a source electrode 510, a drain electrode 520, a protection layer for the source-drain metal 600, and a pixel electrode 700, wherein the gate electrode 200 is formed on the substrate 100, the gate electrode insulation layer 300 is formed on a side of the gate electrode 200 distal to the substrate 100, and the active layer 400 is formed on a side of the gate electrode insulation layer 300 distal to the gate electrode 200, the source electrode 510 and the drain electrode 520 (formed by the source-drain metal 500) are formed on a side of the active layer 400 distal to the gate insulating layer 300, and the protection layer for the source-drain metal 600 covers at least the sidewalls of the source electrode 510 and the drain electrode 520, and exposes a surface of a channel region of the active layer 400.

Hereinafter, the specific structures of the array substrate will be described in detail according to exemplary embodiments of the present disclosure.

According to an embodiment of the present disclosure, the gate electrode 200 may be formed by a first metal, the source electrode 510 and the drain electrode 520 may be formed by a second metal, and the pixel electrode 700 and protection layer for the source-drain metal 600 may be formed by the first transparent conductive layer. Specifically, the first transparent conductive layer may be the ITO.

According to an embodiment of the present disclosure, the protection layer for the source-drain metal 600 covers at least the sidewalls of the source electrode 510 and the drain electrode 520, and exposes a surface of a channel region of the active layer 400. Thereby, the metal at two ends of the source-drain metal 500 can be avoided from being etched once more during etching of the source-drain metal 500 to form the source electrode 510 and the drain electrode 520, such that etched steps at two ends of the source electrode 510 and the drain electrode 520 can be avoided, and thinning of the source electrode and drain electrode, increase of aperture ratio, and increase of pixel density can be achieved. In addition, although the protection layer for the source-drain metal 600 occupies a certain space, it does not affect the aperture ratio since it is formed by the transparent conductive material.

According to an embodiment of the present disclosure and referring to FIGS. 6 and 7, the array substrate may further include a gate electrode line, a common electrode line, a data line (not illustrated), a passivation layer 800, and a common electrode 900. According to an embodiment of the present disclosure, the gate electrode line and the common electrode line are formed by the same material as the gate electrode 200. In other words, the gate electrode line and the common electrode line may be formed by the first metal, and the gate electrode line and the common electrode line are formed in a same layer as the gate electrode 200 and are formed simultaneously with the gate electrode 200. According to an embodiment of the present disclosure, the data line may be formed by the same material as the source electrode 510 and the drain electrode 520. That is, the data line may be formed by the second metal, and the data line is formed in a same layer as the source electrode 510 and the drain electrode 520 and is formed simultaneously with the source electrode 510 and the drain electrode 520. According to an embodiment of the present disclosure, the passivation layer 800 covers at least the protection layer for the source-drain metal 600 and the channel region of the active layer 400, and the passivation layer 800 includes a connecting hole. According to an embodiment of the present disclosure, the common electrode 900 may be formed by the second transparent conductive layer.

According to an embodiment of the present disclosure and referring to FIG. 7, the array substrate may further have a TFT channel 410 subjected to a thinning process. The thinning of the channel region of the active layer 400 facilitates turning-on of the channel, such that the performance of the TFT can be improved.

According to another aspect of the present disclosure, there is provided a display device including the aforementioned array substrate. Thus, the display device may have all the features and advantages of the aforementioned array substrate, for example, the display device may have an increased aperture ratio.

In the description of the present specification, the description referring to the terms “one embodiment”, “another embodiment” and the like means that the specific features, structures, materials, or characteristics described in connection with the embodiment are included in the embodiments. In this specification, descriptions made with reference to the above terms are not necessarily intended to refer to the same embodiment or example, and the specific features, structures, materials, or characteristics described may be combined in a suitable manner in any one or more embodiments or examples. In addition, different embodiments or examples described in this specification and their features may be combined and incorporated with each other by those skilled in the art without conflicting with each other.

Although various embodiments of the present disclosure have been illustrated and described above, it will be understood that the various embodiments described above are exemplary and can not to be construed as limitations to the present disclosure. Those skilled in the art can make modifications, substitutions, and variations to the various embodiments described above within the scope of the present disclosure.

What is claimed is:

1. A method for fabricating an array substrate, comprising the steps of:
forming a gate electrode on a substrate;
forming a gate insulating layer on a side of the gate electrode distal to the substrate;
forming an active layer and a source-drain metal sequentially on a side of the gate insulating layer distal to the gale electrode;
forming a protection layer for the source-drain metal on a side of the source-drain metal distal to the gate insulating layer; and
etching a portion of the source-drain metal corresponding to a channel region to form a source electrode and a drain electrode.

2. The method of claim 1, wherein the step of forming a gate electrode on a substrate comprises the steps of:
depositing a first metal layer on the substrate; and
forming the gate electrode by a first patterning process based on the first metal layer.

3. The method of claim 2, further comprising performing the following step simultaneously with the step of forming the gale electrode on the substrate:
forming a gate electrode line and a common electrode line by the first patterning process based on the first metal layer.

4. The method of claim 1, wherein the step of forming the active layer and the source-drain metal sequentially on the side of the gate insulating layer distal to the gate electrode comprises the steps of:
depositing an active layer film and a second metal layer sequentially on the side of the gate insulating layer distal to the gate electrode; and
forming the active layer and the source-drain metal by a second patterning process based on the active layer film and the second metal layer.

5. The method of claim 4, further comprising performing the following step simultaneously with the step of forming the active layer and the source-drain metal sequentially on the side of the gate insulating layer distal to the gate electrode;
forming a data line by the second patterning process based on the second metal layer.

6. The method of claim 1, wherein the step of forming the protection layer for the source-drain metal on the side of the source-drain metal distal to the gate insulating layer comprises the following steps:
forming a first portion of a first transparent conductive layer on the side of the source-drain metal distal to the gate insulating layer; and
forming the protection layer for the source-drain metal by a third patterning process based on the first portion of the first transparent conductive layer, wherein the protection layer for the source-drain metal covers at least the sidewalls of the source-drain metal and exposes a surface of a portion of the source-drain metal corresponding to the channel region.

7. The method of claim 6, further comprising performing the following steps simultaneously with the step of forming the protection layer for the source-drain metal on the side of the source-drain metal distal to the gate insulating layer:
forming a second portion of the first transparent conductive layer on a portion of the gate insulating layer distal to the gate electrode and without the active layer and the source-drain metal formed thereon; and
forming a pixel electrode by the third patterning process based on the second portion of the first transparent conductive layer.

8. The method of claim 1, wherein the step of etching the portion of the source-drain metal corresponding to the channel region to form the source electrode and the drain electrode comprises the step of:
etching the portion of the source-drain metal corresponding to the channel region by using the protection layer for the source-drain metal as a mask to form the source electrode and the drain electrode.

9. The method of claim 1, further comprising the step of performing the following step simultaneously with the step of etching the portion of the source-drain metal corresponding to the channel region to form the source electrode and the drain electrode:
performing a thinning process to the channel region of the active layer.

10. The method of claim 1, further comprising the step of:
forming a passivation layer by a fourth patterning process, wherein the passivation layer covers at least the protection layer for the source-drain metal and the channel region of the active layer.

11. The method of claim 10, further comprising performing the following step simultaneously with the step of forming the passivation layer:
forming a connecting hole by the fourth patterning process.

12. The method of claim 1, further comprising the step of:
depositing a second transparent conductive layer and forming a common electrode by a fifth patterning process.

13. An array substrate, comprising:
a substrate;
a gate electrode formed on the substrate;
a gate insulating layer formed on a side of the gate electrode distal to the substrate;
an active layer formed on a side of the gate insulating layer distal to the gate electrode;
a source electrode and a drain electrode formed on a side of the active layer distal to the gate insulating layer; and
a pixel electrode and a protection layer for the source-drain metal, wherein the pixel electrode and the protection layer for the source-drain metal are formed by a first transparent conductive layer, and the protection layer for the source-drain metal covers at least sidewalls of the source electrode and the drain electrode and exposes a surface of a channel region of the active layer.

14. The array substrate of claim 13, further comprising:
a gate electrode line and a common electrode line, wherein the gate electrode line, the common electrode line and the gate electrode are formed by a first metal, and the gate electrode line and the common electrode line are formed in a same layer as the gate electrode and are formed simultaneously with the gate electrode;
a data line, wherein the data line and the source electrode and the drain electrode are formed by a second metal, and the data line is formed in a same layer as the source electrode and the drain electrode and is formed simultaneously with the source electrode and the drain electrode;
a passivation layer, wherein the passivation layer covers at least the protection layer for the source-drain metal and the channel region of the active layer, and the passivation layer includes a connecting hole; and
a common electrode, wherein the common electrode is formed by a second transparent conductive layer.

15. A display device, which comprises the array substrate of claim 13.

16. A display device, which comprises the array substrate of claim 14.
